(19) United States
(12) Patent Application Publication
(10) Pub. No.: US 2022/0145488 A1
(43) Pub. Date: May 12, 2022

(54) MULTI-COLOR ELECTRONIC HOUSINGS

(71) Applicant: Hewlett-Packard Development Company, L.P., Spring, TX (US)

(72) Inventors: Kuan-Ting Wu, Taipei City (TW); Chi Hao Chang, Taipei City (TW); Hsing-Hung Hsieh, Taipei City (TW)

(73) Assignee: Hewlett-Packard Development Company, L.P., Spring, TX (US)

(21) Appl. No.: 17/297,163

(22) PCT Filed: Jul. 25, 2019
(86) PCT No.: PCT/US2019/043413

§ 371 Date: May 26, 2021

(51) Int. Cl. C25D 13/22; H05K 5/04; C25D 13/12; C25D 13/20

(52) U.S. Cl. CPC C25D 13/22; C25D 13/20; C25D 13/12; H05K 5/04

(57) ABSTRACT

The present disclosure is drawn to a multi-color electronic housing. The multi-color electronic housing can include a metal alloy having a first portion that can be milled, plasma-treated, and can include an electrodeposited colorant thereon. The metal alloy can further have a second portion that can be milled, plasma-treated, and can include second electrodeposited colorant thereon. The first electrodeposited colorant can provide a different coloration than the second electrodeposited colorant.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market.

### BRIEF DESCRIPTION OF THE DRAWINGS

FIG. 1 graphically illustrates a schematic view of a multi-color electronic housing in accordance with the present disclosure;

FIG. 2 graphically illustrates a schematic view of an example a electronic device in accordance with the present disclosure; and

FIG. 3 is a flow diagram illustrating an example method of manufacturing a multi-color housing for an electronic device in accordance with the present disclosure.

### DETAILED DESCRIPTION

Housings for electronic devices can be cut using computer numerical control (CNC) mills. CNC milling is a machined process that utilizes computer controls and a rotating multi-point cutting tools to cut and shape a substrate and to produce custom designed parts and products. CNC mills can permit automated manufacturing and can provide the benefits of increased accuracy, reduced wastes, increased production speeds, increased safety, increased production efficiency, and reduced production costs.

CNC milled parts can have an “as milled” surface finish, which can be the finish of the substrate material. In some examples, the milled part can be further processed to achieve an aesthetically desired finish. Surface finishes can include bead blast finishing, anodizing, powder coating, and the like. These finishes can provide a uniform finish on the CNC milled part. These finishes do not permit different colorants to be added to different portions of the CNC milled part. Therefore, CNC milling of parts with or without surface finishing can have limited aesthetic design choices.

In accordance with this example and others, the present disclosure is drawn to a multi-color electronic housing. The multi-color electronic housing can include a metal alloy having a first portion that can be milled, plasma-treated, and can include an electrodeposited colorant thereon. The metal alloy can further have a second portion that can be milled, plasma-treated, and can include second electrodeposited colorant thereon. The first electrodeposited colorant can provide a different coloration than the second electrodeposited colorant. In one example, the metal alloy can include an alloy of magnesium, aluminum, lithium, titanium, chromium, nickel, iron, steel, or a combination thereof. In another example, the metal alloy can have an average thickness from about 0.3 mm to about 5 mm. In yet another example, the electrodeposited colorant and the second electrodeposited colorant can be independently deposited at an average thickness from about 5 μm to about 40 μm. In one example, a surface of the multi-color electronic housing can have a gloss value from about 80 gloss units to about 100 gloss units. In another example, the multi-color electronic housing can be in the form of a laptop housing, a desktop housing, a keyboard housing, a mouse housing, a printer housing, a smartphone housing, a tablet housing, a monitor housing, a television screen housing, a speaker housing, a game console housing, a video player housing, an audio player housing, or a combination thereof. In yet another example, the first portion, the second portion, or both can be in the form of a chambered edge.

In another example, an electronic device is presented. The electronic device can include an electronic component for an electronic device and a multi-color electronic housing that can support, encase, or both support and encase the electronic component. The multi-color electronic housing can include a metal alloy that can have a first portion that can be milled, plasma-treated, and can include an electrodeposited colorant thereon. The metal alloy can further have a second portion that can be milled, plasma-treated, and can include second electrodeposited colorant thereon. The first electrodeposited colorant can provide a different coloration than the second electrodeposited colorant. In one example, the electronic device can be a laptop, a desktop computer, a keyboard, a mouse, a smartphone, a tablet, monitor, a television screen, a speaker, a game console, a video player, an audio player, or a combination thereof. In another example, the first portion and the second portion can independently define an opening for a click pad, a fingerprint scanner, a key for a keyboard, a monitor screen, an air vent, or a logo for a laptop. In another example, the first portion, the second portion, or both can be in the form of a chambered edge.

Further presented herein is a method of manufacturing a multi-color electronic housing. The method can include milling a first portion of a metal alloy and a second portion of the metal alloy with a computer numerical control mill; plasma treating the metal alloy after milling; and electrodepositing a first colorant at the first portion and a second colorant at the second portion after plasma treating. The first colorant can provide a different coloration at the first portion than the second colorant at the second portion. In one example, the method can further include placing the metal alloy in a gas chamber that can have a temperature ranging from about 20° C. to about 80° C. and a pressure from about 0.01 torrs to about 3 torrs. A gas in the gas chamber can be a mixture of argon and diatomic oxygen; carbon tetrafluoride; sulfur hexafluoride;

nitrogen trifluoride; a mixture of diatomic oxygen, and nitrogen gas; or a mixture of carbon tetrafluoride and diatomic oxygen. The metal alloy can be irradiated with plasma energy at from about 700 mJ/cm² to about 4,000 mJ/cm². In another example, the electrodepositing can include cathodic or anodic electrodepositing of the first and the second colorant in an electrophoretic bath solution; and curing the metal alloy at from about 120° C. to about 180° C. for a time period that can range from about 15 minutes to about 120 minutes. In yet another example, the method can further include forming a passivation layer on the metal alloy at from about 3 μm to about 25 μm by micro-arc oxidation prior to milling.

It is noted that when discussing the multi-color electronic housing, the electronic device, or the method of manufacturing the multi-color electronic housing, such discussions of one example are to be considered applicable to the other examples, whether or not they are explicitly discussed in the context of that example. Thus, in discussing a metal alloy in the context of the multi-color electronic housing, such disclosure is also relevant to and directly supported in the context of the electronic device, the method of manufacturing the multi-color electronic housing, and vice versa.

### Multi-Color Electronic Housings

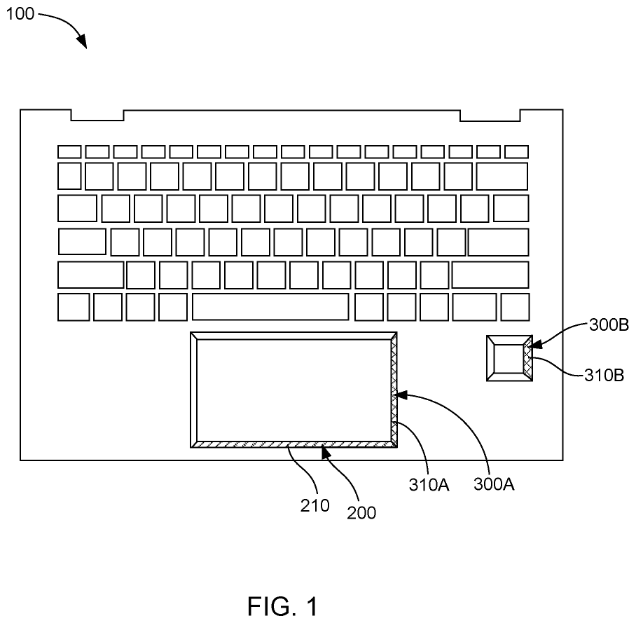

As illustrated in FIG. 1, a multi-color electronic housing 100, can include a metal alloy having a first portion 200 that can be milled, plasma treated, and can include an electrodeposited colorant 210 (shown as diagonal hatching in this example).The metal alloy can further have a second portion 300A and/or 300B that can be milled, plasma treated, and can include a second electrodeposited colorant 310A and/or 310B (shown as cross hatching in this example). Note that the second portion can be part of the same opening partially defined by the first portion which exposes a human interface device, e.g., click pad, or can at a different opening exposing a different human interface device, e.g., fingerprint scanner. It may be also that the first portion and/or the second portion do not define an opening, but rather are positioned at an edge of the multi-color electronic housing. Regardless, in any of these arrangements, the first electrodeposited colorant can provide a different coloration than the second electrodeposited colorant.

While this specification refers to a first portion and a second portion respectfully, which includes the electrodeposited colorant and a second electrodeposited colorant, a quantity of portions of the multi-color electronic housing is not limited. A multi-color electronic housing can include a different portion with a different electrodeposited colorant for some or all of the openings on the multi-color electronic housing. For example, a multi-colored electronic housing could be for a keyboard and could have a portion with a different electrodeposited colorant for individual key openings, e.g., from about 50 to about 120, from about 70 to about 110, or from about 80 to about 105 keys or other human interface device openings. Alternatively, groups of keys or other human interface devices on the keyboard (or other electronic device) can be grouped into subcategories with colorations that provide a visual cue relative to the respective groupings (whether adjacently grouped and or merely grouped by coloration and not by spatial relationship).

Turning now to the components of the multi-colored electronic housing in further detail. The multi-color electronic housing can include a metal alloy. Metal alloys can exhibit low weight and high strength. The metal alloy can be an alloy of magnesium, aluminum, lithium, titanium, chromium, nickel, iron, steel, or a combination thereof. In one example, the metal alloy can include a magnesium alloy. In some examples, the magnesium alloy can include AZ31B, AZ61, AZ60, AZ80, AM60B, LZ91, LZ14, ALZ691, AZ91D, or an alloy thereof. In yet another example, the metal alloy can include an aluminum alloy. In a further example, the metal alloy can include stainless steel.

The metal alloy can be shaped to house any type of electronic components of an electronic device, including the specific types of electronic devices described herein. In some examples, a metal alloy can have a thickness suitable for a particular type of electronic device. In some examples, a thickness can vary based on the metal alloy and the desired strength of the alloy for supporting electronic components therein. In one example, the metal alloy can have an average thickness that can range from about 0.3 mm to about 5 mm. As used herein, an “average thickness” indicates a numerical average of a cross-sectional size. In another example, the metal alloy can have an average thickness that can range from about 0.3 mm to about 2 mm. In yet other examples, the metal alloy can have an average thickness that can range from about 0.5 mm to about 2.5 mm, from about 1 mm to about 3 mm, from about 2 mm to about 4 mm, or from about 0.75 mm to about 1.5 mm.

The metal alloy can be milled using computer numerical control (CNC) mill. The metal alloy can be diamond cut to form a chamber, e.g. opening and a chambered edge in the metal alloy. The milled area can be plasma treated. Plasma treatment can remove organic chemicals on the metal alloy that can be left behind following CNC milling. The removal of organic chemicals can permit the electrodepositing of a colorant at an opening or a sidewall chamber of the metal alloy. The electrodepositing can permit different colorants at different openings and/or chamber edges of a multi-color electronic housing. In some examples, the first portion, the second portion, or both can be at a chambered edge.

The electrodeposited colorant can include a pigment, a dye, or a combination thereof. Example pigments can include carbon black, titanium dioxide, clay, mica, aluminum powder, talc, barium sulfate, calcium carbonate, synthetic pigment, metallic powder, aluminum oxide, graphene, pearl pigment, or a combination thereof. Example dyes can include aluminum-based water-soluble dyes, tetraphenyldiamine-based water-soluble dyes, cyanine-based water-soluble dyes, dithiolene-based water-soluble dyes, ALEXA FLOUR™ 594 dye (available from ThermoFisher Scientific, USA), pacific orange, quinoline yellow WS, 3-carboxy-6,8-difluoro-7-hydroxycoumarin (aka pacific blue dye), or a combination thereof. In one example, an electrodeposited colorant, a second electrodeposited colorant, or a combination thereof can be deposited at a thickness that can range from about 5 μm to about 40 μm. In other examples, an electrodeposited colorant, a second electrodeposited colorant, or a combination thereof can be deposited at a thickness that can range from about 15 μm to about 30 μm, from about 10 μm to about 20 μm, from about 5 μm to about 25 μm, or from about 20 μm to about 40 μm.

The multi-color electronic housing can have a glossy or metallic luster surface. Glossy surfaces can be quantified in gloss units. As used herein, gloss units refer to an amount of light that is reflected off a surface of the multi-color electronic housing as measured by a gloss meter directed at a 60° angle to a surface of the multi-color electronic housing. In one example, the multi-color housing can have a gloss value that can range from about 80 gloss units to about 100 gloss units. In yet other examples, a multi-color color housing can have a gloss value that can range from about 85 gloss units to 95 gloss units or from about 80 gloss units to about 90 gloss units.

The multi-color electronic housing can have a durable surface that can exhibit high corrosion resistance. In some examples, the multi-color electronic housing can pass a 96 hours salt fog test. The salt fog test can include spraying the multi-color electronic housing with a 5% salt solution for 24 hours, followed by drying for 24 hours, followed by a second spraying with the salt solution for 24 hours, and a second drying for 24 hours. The salt solution can have a temperature that can range from about 33° C. to about 37° C. In some examples, the salt fog test can comply with MIL-STD-810F environmental and engineering testing standard dated Jan. 1, 2000. As used herein, a passing result can occur when a multi-color electronic housing does not exhibit visible corrosion following the 96 hours salt fog test.

The multi-color electronic housing can be used to enclose and/or support and electronic component of any electronic device. In some examples, the multi-color electronic housing can be a laptop housing, a desktop housing, a keyboard housing, a mouse housing, a printer housing, a smartphone housing, a tablet housing, a monitor housing, a television screen housing, a speaker

(Removing an extra space in between) housing, a game console housing, a video player housing, an audio player housing, or a combination thereof. In an example, the housing can be a keyboard housing. In another example, the housing can be a laptop housing.

### Electronic Devices

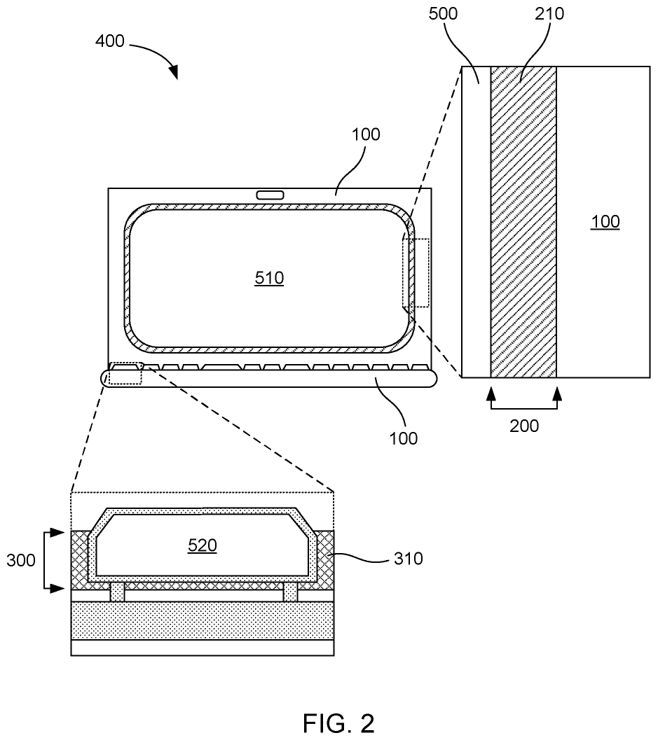

In another example, an electronic device 400 is shown in FIG. 2, which can include an electronic component 510, 520, 530 for an electronic device and a multi-color electronic housing 100 that can support, encase, or both support and encase the electronic component. The electronic component in this example is represented by a laptop computer screen at 510 and a keyboard human interface device 520 including a button and the circuitry associated therewith, but it is understood that there are other electronic components that can be encased and/or supported, including electronic components in this example, e.g., computer circuit boards, finger print scanners, track or click pads, power supply assemblies, peripheral interfaces, etc. The multi-color electronic housing can include a metal alloy having a first portion 200 that can be milled, plasma-treated, and can include an electrodeposited colorant 210 thereon (shown as diagonal hashing in this example). The metal alloy can further have a second portion 300 that can be milled, plasma-treated, and can include second electrodeposited colorant 310 thereon (shown as cross hatching in this example). The first electrodeposited colorant can provide a different coloration than the second electrodeposited colorant.

A variety of electronic devices can be manufactured to include the multi-color electronic housings described herein. In various examples, such electronic devices can include various electronic components encased and/or supported by the multi-colored electronic housing. As used herein, “encased” or “encasing” when used with respect to the housing can include housings that can completely enclose the electronic components or partially enclose the electronic components of an electronic device. Certain electronic components may be designed to be exposed through an opening in the housing, such as display screens, keyboard keys, buttons, fingerprint scanners, cameras, and so on. Accordingly, the multi-color electronic housing described herein can include openings for these electronic components. Other electronic components may be designed to be completely encased, such as motherboards, CPUs, fans, hard drives, graphic cards, batteries, sim cards, wireless transceivers, memory storage drives, and so on.

In a further example, the electronic device can be a laptop, a desktop computer, a keyboard, a mouse, a smartphone, a tablet, monitor, a television screen, a speaker, a game console, a video player, an audio player, or a combination thereof. In some examples, the first portion and the second portion can independently define an opening for a click pad, a fingerprint scanner, a key for a keyboard, a monitor screen, an air vent, or a logo for a laptop. In one example, a portion can define an opening for a decorative location.

### Methods of Manufacturing Multi-Color Housings for Electronic Devices

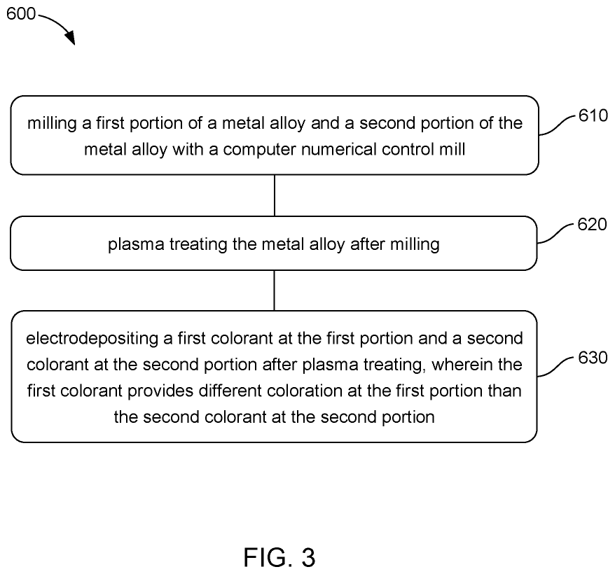

Further presented herein is a method 600 of manufacturing a multi-color electronic housing, shown by a flow diagram in FIG. 3. The method can include milling 610 a first portion of a metal alloy and a second portion of the metal alloy with a computer numerical control mill; plasma treating 620 the metal alloy after milling; and electrodepositing 630 a first colorant at the first portion and a second colorant at the second portion after plasma treating. The first colorant can provide a different coloration at the first portion than the second colorant at the second portion. In one example, the method can include forming a passivation layer on the metal alloy at from about 3 μm to about 25 μm by micro-arc oxidation prior to milling.

In further detail, the method can also include, micro-arc oxidation, passivation treatment, degreasing, spray coating, and/or transparent passivation treatment. In one example, the method can include micro-arc oxidation, followed by spray coating, followed by milling, followed by degreasing, followed by plasma treating, followed by a transparent passivation treatment, followed by electrodepositing. In some examples, the previous method can be followed by a second milling, followed by a second degreasing, followed by second plasma treating, followed by a second transparent passivation treatment and followed by second electrodepositing. The second milling and electrodepositing can allow for controlled electrodeposition of a second colorant at a second portion of a multi-color electronic housing. The method can further include washing the metal alloy in preparation for various stages and between various stages in an ultrasonic deionized water bath. Each of the various stages in the method are discussed in further detail below.

### Micro-Arc Oxidation Treatment

Some metal alloys can be easily oxidized at the surface, and may be vulnerable to corrosion or other chemical reactions. For example, magnesium or magnesium alloys in particular can have a somewhat porous surface that can be vulnerable to chemical reactions and corrosion. Micro-arc oxidation can be used to form a protective layer at the surface of the metal alloy that can increase the chemical resistance, hardness, and durability of the metal alloy.

Micro-arc oxidation is an electrochemical process where a surface of a metal alloy is immersed in a chemical bath and treated using micro-discharges of compounds. The chemical bath can include water with from about 3 wt % to about 15 wt % of an electrolytic compound. The electrolytic compound can include sodium silicate, sodium phosphate, potassium fluoride, potassium hydroxide, sodium hydroxide, fluorozirconate, sodium hexametaphosphate, sodium fluoride, aluminum oxide, silicon dioxide, ferric ammonium oxalate, phosphoric acid salt, or any combinations thereof. A temperature of the chemical bath can range from about 20° C. to about 40° C. or from about 25° C. to about 35° C.

A high-voltage alternating current can be applied to the metal alloy and the metal alloy can effectively act as a working electrode. A high-voltage alternating current can also be applied to a counter electrode that can also be immersed in the chemical bath. The applied voltage can range from about 250 V to about 700 V. In yet other examples, the applied voltage can range from about 300 V to about 600 V, from about 250 V to about 500 V, or from about 400 V to about 700 V.

A time period of the submersion can correlate to a thickness of an oxidation layer formed thereon. In one example, the metal alloy can be submerged in the chemical bath for from about 5 minutes to about 20 minutes. In some examples, the oxidation layer formed on the metal alloy can have an average thickness that can range from about 3 μm to about 25 μm. In yet other examples, an average thickness of the oxidation layer formed thereon can range from about 5 μm to about 25 μm, from about 10 μm to about 20 μm, or from about 7 μm to about 15 μm.

### Passivation Treatment

In some examples, a passivation treatment can be applied to a surface of the metal alloy in place of micro-arc oxidation to form a protective passivation layer at the surface of the metal alloy. The metal alloy can be submerged in a passivation chemical bath.

The metal alloy can be subjected to the passivation treatment for a time period ranging from about 15 seconds to about 60 seconds. The time period of the treatment can correlate to a thickness of a passivation layer formed thereon. In some examples, the passivation layer formed on the metal alloy can have an average thickness that can range from about 1 μm to about 5 μm. In yet other examples, an average thickness of the passivation layer formed thereon can range from about 2 μm to about 5 μm, from about 1 μm to about 3 μm, or from about 3 μm to about 5 μm.

The passivation layer formed on the metal alloy can include a phosphate salt layer, a calcium phosphate layer, a molybdate layer, a vanadate layer, a phosphate layer, a chromate layer, a stannate layer, a manganese salt layer, or any combinations thereof.

### Milling—Computer Numerical Control Mill

The milling can include cutting the metal alloy on a computer numerical control mill. In one example, the milling can include a diamond cut. In some examples, milling can include a CNC cutting fluid. A location of the milling on the metal alloy is not limited and can depend on the desired form of the multi-color electronic housing.

### Degreasing

Degreasing is an alkaline cleaning process used to remove debris from a surface of the metal alloy. Degreasing can include submerging a metal alloy in a cleaning solution including water and from about 0.3 wt % to about 2.0 wt % of sodium caseinate, sodium polyacrylate, sodium polyoxyethylene alkyl ether carboxylate, sodium dodecyl sulfate, or a mixture thereof for a time period ranging from about 30 seconds to about 180 seconds.

### Ultrasonic Deionized Water Bath

In some examples, the metal alloy can be cleaned with deionized water. The deionized water can be heated at from about 15° C. to about 50° C. and placed in an ultrasonic bath. The ultrasonic bath can have a vibration rate of from about 10 kHz to about 200 kHz and the metal alloy can be submerged in the ultrasonic bath for a time period ranging from about 15 seconds to about 180 seconds.

### Coating—Spray or Electrostatic

In some examples, the method can include spray coating or electrostatically coating a surface of the metal alloy for aesthetic purposes. Electrostatic coating can be used to a powder coat. Spray coating can be used to apply a primer coat, a base coat, a top coat, or a combination thereof.

A powder coat can include an epoxy, polyvinyl chloride, polyamides, polyesters, polyurethanes, acrylics, polyphenylene ether, or the like. The powder coat can be electrostatically applied to a surface of the metal alloy. In some examples applying a powder coat can include curing the surface of the metal alloy at a temperature ranging from about 120° C. to about 190° C. for about 20 minutes to about 30 minutes. The powder coat can be applied at a thickness that can range from about 20 μm to about 60 μm.

A primer coat can include a polyester, polyurethane, or a combination thereof that can be applied to a surface of the metal alloy. The primer coat can be cured by baking the surface at a temperature that can range from about 60° C. to about 80° C. for a time period that can range from about 15 minutes to about 40 minutes. The primer coat can be applied at a thickness that can range from about 5 μm to about 20 μm.

A base coat can include polyester, polyurethane and polyurethane copolymers with pigments including carbon black, titanium dioxide, clay, mica, talc, barium sulfate, calcium carbonate, synthetic pigment, metallic powder, aluminum oxide, organic powder, inorganic powder, plastic bead, color pigment, dye, or any combination thereof. The base coat can be cured by baking the surface of the metal alloy at a temperature ranging from about 60° C. to about 80° C. for a time period ranging from about 15 minutes to about 40 minutes. The base coat can be applied at a thickness that can range from about 10 μm to about 20 μm.

A top coat can include a polyurethane coat and/or a ultra-violet coat. A polyurethane coat can include a polyurethane, a polyurethane copolymer, or both a polyurethane and a polyurethane copolymer. The polyurethane coat can be cured at a temperature that can range from about 60° C. to about 80° C. for a time period that can range from about 15 minutes to about 40 minutes. An ultra-violet coat can include a polyacrylic, a polyurethane, a urethane acrylate, an acrylic acrylate, an epoxy acrylate, or any combinations thereof. The ultra-violet coat can be cured at temperature that can range from about 50° C. to about 60° C., for a time period of from about 10 minutes to about 15 minutes, followed by UV exposure to a light having an energy ranging from about 700 mJ/cm² to about 1,200 mJ/cm² for from about 10 seconds to about 30 seconds. The polyurethane coat, the ultra-violet coat, or both the polyurethane coat and the ultra-violet coat can be independently applied at a thickness that can range from about 10 μm to about 25 μm.

The spray coating can be from about one layer to about four layers thick. In some examples, spray coating can include a primer coat, a base coat, and a top coat. In another example, spray coating can include a primer coat and a top coat. In yet another example, the coating can include a powder coat. In a further example, spray coating can include a top coat.

### Plasma Treatment

In some examples, a plasma treatment can include placing the metal alloy in a gas chamber having a temperature ranging from about 20° C. to about 80° C. and a pressure from about 0.01 torrs to about 3 torrs. A gas in the gas chamber can include a mixture of argon and diatomic oxygen; carbon tetrafluoride; sulfur hexafluoride; nitrogen trifluoride; a mixture of diatomic oxygen, and nitrogen gas; or a mixture of carbon tetrafluoride and diatomic oxygen. The metal alloy can be irradiated in the gas chamber with plasma energy ranging from about 700 mJ/cm² to about 4,000 mJ/cm².

### Transparent Passivation Treatment

A transparent passivation treatment can be used to form a transparent passivation layer at an exposed portion of a metal alloy following milling of the metal alloy. Transparent passivation treatments may include immersing the metal alloy in a passivation treatment so that all surfaces of the metal alloy are contacted by reagents. However, in some examples, the passivation treatment may affect the exposed metal alloy while having no effect on surfaces of the metal alloy that have been coated or treated. In some examples, a transparent passivation layer may not be a discrete layer that is applied similarly to that of a spray coating, for example, but can become infused or otherwise become part of the metal alloy at or near a surface of the chambered edge.

A passivation treatment can include a chelating agent, a metal ion, a chelated metal complex, or a combination thereof. The chelating agent can include ethylenediaminetetraacetic acid; ethylenediamine; nitrilotriacetic acid; diethylenetriaminepenta(methylenephosphonic acid); nitrilotris(methylenephosphonic acid); 1-hydroxyethane-1,1-disphosphonic acid; phosphoric acid; or any combinations thereof. The metal ion can include an aluminum ion, an indium ion, a nickel ion, a chromium ion, a tin ion, or a zinc ion.

In some examples, a pH of the passivation treatment can range from about 3 to about 7. The metal alloy can be submerged in the passivation treatment for from about 30 seconds to 180 seconds. The transparent passivation layer formed can have an average thickness that can range from about 30 nm to about 1 μm, or from about 10 nm to about 1 μm.

### Electrode Positing Colorant

In an example, electrodepositing a colorant can include cathodic or anodic electrodeposition. During electrodeposition the metal alloy can be submerged in an electrophoretic bath solution. The electrophoretic bath solution can include polyacrylic polymer, polyacrylamide-acrylic copolymer, epoxy-containing polymer, or any combinations thereof. The electrophoretic bath solution can further include a pigment or dye to be deposited on the metal alloy. A charge can be applied to the electrophoretic bath solution that can range from about 30 V to about 150 V. The metal alloy can be submerged in the electrophoretic bath solution at from 30 seconds to about 120 seconds.

In some examples, the electrodeposition can be followed by curing. Curing the metal alloy can occur at a temperature that can range from about 120° C. to about 180° C. for a time period ranging from about 15 minutes to about 120 minutes.

### DEFINITIONS

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can be dictated by the particular variable and can be determined based on experience and the associated description herein.

As used herein, “housing” refers to the exterior shell of an electronic device. In other words, the housing contains the internal electronic components of the electronic device. The housing is an integral part of the electronic device. The term “housing” is not meant to refer to the type of removable protective cases that are often purchased separately for an electronic device (especially smartphones and tablets) and placed around the exterior of the electronic device.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics, or other opaque particles, whether or not such particles impart color. Thus though the present description primarily exemplifies the use of pigment colorants, the term “pigment” can be used more generally to describe pigment colorants and other pigments such as organometallics, ferrites, ceramics, etc. In one specific example, however, the pigment is a pigment colorant.

As used herein, a plurality of items, structural elements, compositional elements, and/or materials may be presented in a common list for convenience. However, these lists should be construed as though members of the list is individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if numerical values and sub-ranges is explicitly recited. For example, a weight ratio range of about 1 wt% to about 20 wt % should be interpreted to include not only the explicitly recited limits of 1 wt % and about 20 wt %, but also to include individual weights such as 2 wt %, 11 wt %, 14 wt %, and sub-ranges such as 10 wt % to 20 wt %, 5 wt % to 15 wt %, etc.

While the present technology has been described various modifications, changes, omissions, and substitutions can be made without departing from the spirit of the disclosure. It is intended, therefore, that the disclosure be limited by the scope of the following claims.

What is claimed is:

1. A multi-color electronic housing, comprising a metal alloy including:
a first portion that is milled, plasma-treated, and includes an electrodeposited colorant thereon; and
a second portion that is milled, plasma-treated, and further includes second electrodeposited colorant thereon,
wherein the first electrodeposited colorant provides different coloration than the second electrodeposited colorant.

2. The multi-color electronic housing of claim 1, wherein the metal alloy includes an alloy of magnesium, aluminum, lithium, titanium, chromium, nickel, iron, steel, or a combination thereof.

3. The multi-color electronic housing of claim 1, wherein the metal alloy has an average thickness from about 0.3 mm to about 5 mm.

4. The multi-color electronic housing of claim 1, wherein the electrodeposited colorant and the second electrodeposited colorant are independently deposited at an average thickness from about 5 μm to about 40 μm.

5. The multi-color electronic housing of claim 1, wherein a surface of the multi-color electronic housing has a gloss value from about 80 gloss units to about 100 gloss units.

6. The multi-color electronic housing of claim 1, in the form of a laptop housing, a desktop housing, a keyboard housing, a mouse housing, a printer housing, a smartphone housing, a tablet housing, a monitor housing, a television screen housing, a speaker housing, a game console housing, a video player housing, an audio player housing, or a combination thereof.

7. The multi-color electronic housing of claim 1, wherein the first portion, the second portion, or both are in the form of a chambered edge.

8. An electronic device comprising:
an electronic component for an electronic device; and
a multi-color electronic housing supporting, encasing, or both supporting and encasing the electronic component, the multi-color electronic housing including a metal alloy having:
a first portion that is milled, plasma-treated, and includes an electrodeposited colorant thereon, and
a second portion that is milled, plasma-treated, and further includes second electrodeposited colorant thereon,
wherein the first electrodeposited colorant provides different coloration than the second electrodeposited colorant.

9. The electronic device of claim 8, wherein the electronic device is a laptop, a desktop computer, a keyboard, a mouse, a smartphone, a tablet, monitor, a television screen, a speaker, a game console, a video player, an audio player, or a combination thereof.

10. The electronic device of claim 8, wherein the first portion and the second portion independently define an opening for a click pad, a fingerprint scanner, a key for a keyboard, a monitor screen, an air vent, or a logo for a laptop.

11. The electronic device of claim 8, wherein the first portion, the second portion, or both are in the form of a chambered edge.

12. A method of manufacturing a multi-color housing for an electronic device, comprising:
milling a first portion of a metal alloy and a second portion of the metal alloy with a computer numerical control mill;
plasma treating the metal alloy after milling; and
electrodepositing a first colorant at the first portion and a second colorant at the second portion after plasma treating,
wherein the first colorant provides different coloration at the first portion than the second colorant at the second portion.

13. The method of claim 12, wherein plasma treating includes:
placing the metal alloy in a gas chamber having a temperature ranging from about 20° C. to about 80° C. and a pressure from about 0.01 torrs to about 3 torrs wherein a gas in the gas chamber is a mixture of argon and diatomic oxygen; carbon tetrafluoride; sulfur hexafluoride; nitrogen trifluoride; a mixture of diatomic oxygen, and nitrogen gas; or a mixture of carbon tetrafluoride and diatomic oxygen; and
irradiating the metal alloy with plasma energy at from about 700 mJ/cm² to about 4,000 mJ/cm².

14. The method of claim 12, wherein electrodepositing includes:
cathodic or anodic electrodepositing the first and the second colorant in an electrophoretic bath solution; and
curing the metal alloy at from about 120° C. to about 180° C. for a time period ranging from about 15 minutes to about 120 minutes.

15. The method of claim 12, further comprising forming a passivation layer on the metal alloy at from about 3 μm to about 25 μm by micro-arc oxidation prior to milling.
